(19) United States
(12) Patent Application Publication
(10) Pub. No.: US 2006/0255405 A1
(43) Pub. Date: Nov. 16, 2006

(54) Fully-depleted SOI MOSFET device and process for fabricating the same

(75) Inventors: Bing-Yue Tsui, Hsinchu (TW); Chia-Pin Lin, Sinpu Township (TW)

Correspondence Address: BUCKNAM AND ARCHER, 1077 NORTHERN BOULEVARD, ROSLYN, NY, 11576, US

(73) Assignee: National Chiao Tung University, Hsinchu (TW)

(21) Appl. No.: 11/231,624

(22) Filed: Sep. 21, 2005

(30) Foreign Application Priority Data
May 12, 2005 (TW) 09115388

(51) Int. Cl. H01L 21/8238; H01L 27/12; H01L 29/76; H01L 29/94; H01L 21/44

(52) U.S. Cl. 257/347; 257/382; 257/412; 438/216; 438/683; 257/E21.439

(57) ABSTRACT

The present invention proposes a nano-scale high-performance SOI MOSFET device and a process for manufacturing the same. The device is characterized by comprising: a metal oxide semiconductor, formed on the SOI substrate; a silicide layer (05), wherein a gate consists of a single full silicide gate (10), a high-K dielectric layer (08) and a part for work function modification (09); and source/drain (6) are complete through a silicide reaction and has a modified Schottky junction.

### BACKGROUND OF THE INVENITON

1. Field of the Invention

The present invention proposes a nano-scale high-performance SOI MOSFET device and a process for fabricating the same. The device can resolve ploy-gate depletion phenomenon, and has characteristics of high driving current, low gate/source/drain sheet resistance, low gate/drain leakage current, low source/drain edge electric field, low temperature process, etc.

2. Description of the Related Art

With the miniaturization of devices, conventional gate dielectric SiO2 is expected to be replaced by high dielectric constant (high-k) dielectrics. The structures of poly-gate and high-k layer for a traditional MOSFET structure may cause a lot of disadvantages, such as gate depletion phenomenon which limits the decrease of equivalent oxide thickness (EOT), high resistance which blocks high-frequency operations, boron penetration which creates threshold voltage drift, because the poly-gate a semiconductor material. In order to improve the above disadvantages, the process of forming a metal electrode with a high-K insulating layer has been widely studied, so that the characteristics and reliability of devices are enhanced.

A paper “Sub-100 nm Gate Length Metal Gate NMOS Transistors Fabricated by a Replacement Gate Process,” IEDM conference, 1997, A. Chatterjcc discloses that source/drain are first formed, and then a metal gate is manufactured by a replacement method together with chemical mechanical polishing (CMP). Although it attempts to resolve the problem of source/drain high temperature activation, it increases manufacture difficulty and decreases the reliability of devices. Meanwhile, it is necessary to use two metal gates to meet the work functions required by N-type and P-type field effect transistors respectively.

Moreover, a paper “Low Temperature MOSFET Technology with Schottky Source/Drain, High-K Gate Dielectrics and Metal Electrode,” SDRS conference, 2003, Shiyang Zhu, first successfully adopted a low temperature silicide process instead of traditional source/drain process so as to be consistent with metal gate/high-K dielectric layer process. Although it resolves the problem of source/drain high temperature activation, two different metal gates are required to have proper work function modified and two silicides are required to increase on/off ratio of devices.

In summary of the prior solutions, it is not easy for such metal gate/high-K insulating layer structure to be compatible with the source/drain high temperature activation process for traditional MOSFETs; however, it is easy to create the problems of metal deterioration, reaction between metal and dielectric layer and increased thickness of high-K insulating layer. Also, a single metal gate cannot satisfy the work function requirements for both the N-type and P-type field effect transistors.

Therefore, there are new research and development trends. For example, a paper “Transistors with Dual Work Function Metal Gates by Single Full Silicidation (FUSI) of Polysilicon Gates,” IEDM conference, 2002, W. P. Maszara, first successfully utilized a single silicide while modified work functions required by N-type and P-type devices. Recently, a paper “A Novel 25 nm Modified-Schottky-Barrier FinFET with High Performance,” EDL, 2004, B. Y. Tsui first found that a process of modifying schottky barrier at the junction of silicide and silicon by implanting ions into the silicide can be applied to nano-scale devices. As compared with the prior methods, it not only can use the same silicide on the sources/drains of the N-type and P-type devices, but also maintains the advantages of low temperature silicide process while obtains better characteristics of the devices.

### SUMMARY OF THE INVENTION

In view of the prior art and the new trends, the first object of the present invention is to provide a nano-scale transistor which can resolve ploy-gate depletion phenomenon, and has characteristics of high driving current, low gate/source/drain sheet resistance, low gate/drain leakage current, low source/drain edge electric field, etc. Also, the nano-scale transistor is a high-performance SOI MOSFET, meeting a nano-scale requirement. The fully-depleted SOI MOSFET device (shown in FIG. 1) comprises:

a SOI substrate, being a base material of the device and having a silicon substrate (01) and an insulating layer (02) located on the silicon substrate;

a metal oxide semiconductor, formed on the SOI substrate;

a silicide layer (05), wherein a gate structure has a single full silicide gate (10), a high-K dielectric layer (08) and a part for work function modification (09); and source/drain (6) are fully reacted silicides and have modified Schottky junctions.

The gate dielectric layer (08) is at least selected from a thermal oxide layer or one of various high-K dielectric layers. The silicide (05) is selected from various suitable silicides.

Another object of the present invention is to provide a process for fabricating the SOI MOSFET. As compared with the prior methods, we find that a simpler and more efficient low temperature process, comprising:

providing a SOI substrate, which serves as a base material of the device and has a silicon substrate (01) and an insulating layer (02) located on the silicon substrate;

forming a metal oxide semiconductor on the SOI substrate by using a semiconductor process;

selecting a silicide layer with a mid-gap work function characteristic and a proper high-k dielectric layer, while forming source/drain/gate as fully reacted suicides simultaneously;

implanting proper ions into the source/drain/gate silicides so as to perform low temperature diffusion.

In the method of the present invention, on one hand, for the gate characteristic, the work function can be efficiently modified because the ions are accumulated between the silicide gate and the gate high-K insulating layer; on the other hand, for the source/drain, since the ions implanted into the source/drain silicide layers do not damage the channel silicon layer, it is unnecessary to perform high temperature annealing to remove implantation damages, and thus, the silicide gate and the high-K insulating layer can be prevented from having the problem of thermal stability caused by the high temperature annealing.

As to the adjustments of implanting dose and annealing conditions, not only the setting for the work function of the gate can be adjusted, but also the outside concentrations of the source and drain can be controlled and the property of Schottky junction can be modified. Subsequent processes, such as the processes of forming contact windows and metal wires, are the same as those of traditional devices. In another method, before performing the metal salicide process, proper impurities are implanted into metal by ion implantation.

While annealing process is performed to fully react the source/drain into silicide, implanted ions are diffused and accumulated between the silicide gate and the gate dielctric layer to form a high concentration region for work function modification, and at the junction between the source/drain silicides and the channel to modify Schottky barrier, thereby forming modified Schottky junctions.

The present invention can efficiently simplify the device process by forming a single fully reacted silicide for the gate/source/drain simultaneously.

The present invention can efficiently achieve a single silicide gate and modify the work function required by N-type and P-type devices simultaneously by implanting ions into silicide and then diffusing into the junction of the silicide and high-K dielectric layer to form an extremely thin high concentration diffusion region between the fully reacted silicide gate and high-K dielectric layer.

Meanwhile, the present invention can form an extremely thin high concentration diffusion region (very suitable for sources/drains of nano devices) outside the fully reacted silicide source/drain with a thermal budget lower than that of the traditional process by implanting ions into metal or silicide and then diffusing into the silicon substrate. Moreover, the problem of thermal stability on the high-K dielectric layer caused by performing high temperature annealing after ion implanting on the source/drain in the traditional process can be resolved.

The present invention forms an extremely thin high concentration diffusion region outside the silicidized source and drain so as to lower the Schottky barrier between the source or drain and the channel by implanting ions into metal or silicide and then diffusing into the silicon substrate.

The present invention forms the modified Schottky junction so as to greatly reduce leakage current at the drain junction by using the high concentration region outside the source and drain.

The present invention reduces the electric field at the edges of the source and drain so as to enhance the reliability of the device by using the diffusion region on the both sides of the source and drain.

### BRIEF DESCRIPTION OF THE DRAWINGS

FIG. 1 is a cross-sectional view of an embodiment of the present invention.

FIGS. 2A-2D are views showing a process according to an embodiment of the present invention.

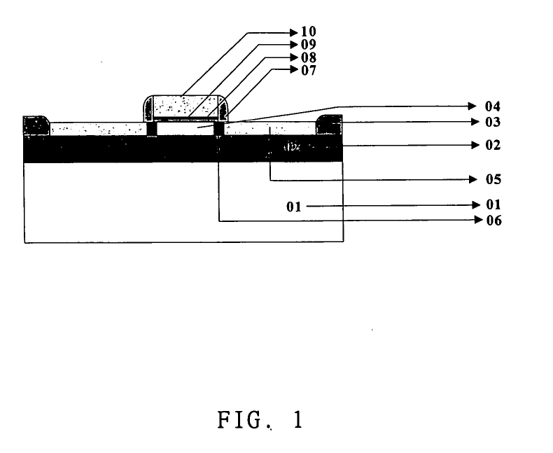

### DESCRIPTION OF THE PREFERRED EMBODIMENTS

Those skilled in the art will more fully understand the technology, ways and features of the present invention adopted for achieving the above objects from an exemplary preferred embodiment and the accompanying drawings.

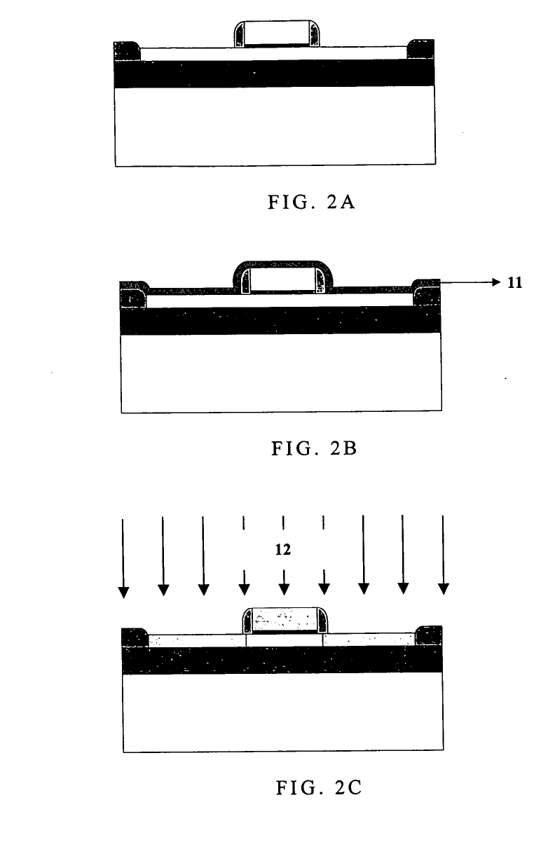

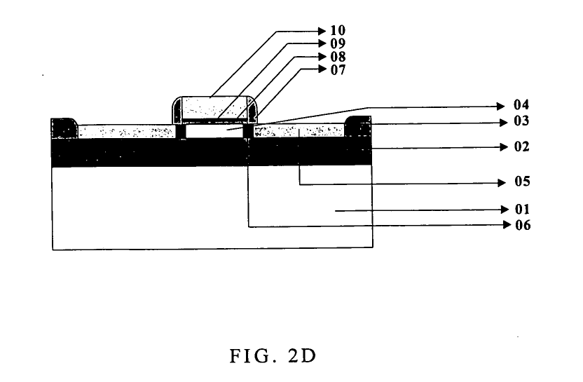

As shown in FIG. 2, the method of the present invention comprises:

first, forming an isolating structure between devices on a SOI silicon chip by using a general isolation process and defining an active region;

next, depositing a gate dielectric layer (for example, a traditional dry silicon oxide film or a high-K dielectric layer), a poly gate electrode having a proper thickness (similar to the thickness of the active region), and then forming a gate insulating layer and a poly gate by deposition, photolithography and etch processes;

Subsequently, further depositing a dielectric isolating layer and forming gate spacers by anisotropic etch process;

Next, depositing a metal layer on the chip and fully depleting the silicon of the poly gate and the source/drain simultaneously by metal salicide process, and forming fully reacted silicide gate and source/drain having Schottky barrier;

Then, implanting proper impurities into the full silicides of the gate, source and drain by ion implantation;

Next, performing low temperature annealing process, wherein for the gate structure, implanted ions are diffused into the region between the full silicide gate and the gate dielectric layer and accumulated to form a high concentration region, thereby efficiently achieving the objects of forming a signal silicide gate and modifying the work function required by the N-type and P-type devices, and for the source/drain, implanted ions are diffused into the outside of the source and drain silicides and accumulated to form a high concentration region, thereby forming modified Schottky junctions with silicde, such that the drain junction leakage current is greatly reduced, and the electric field intensity at the edges of the source and drain is decreased by using the diffusion region on the both sides of the source and drain so as to enhance the reliability of the devices.

Although the invention has been disclosed in terms of preferred embodiment, the disclosure is not intended to limit the invention. Those skilled in the art can make changes and modifications within the scope and spirit of the invention which is determined by the claims below.

### LIST OF MAJOR ELEMENTS AND ITS CORRESPONDING REFERENCE NUMERALS

01 silicon substrate
02 insulating layer
03 isolating layer
04 silicon layer
05 silicide layer
06 high concentration diffusion region
07 spacers
08 gate high-K insulating layer
09 high concentration diffusion region
10 silicide gate electrode
11 metal layer
12 ion implantation

What is claimed is:

1. A fully-depleted SOI MOSFET device, comprising:
a SOI substrate, being a base material of the device, having a silicon substrate (01) and an insulating layer (02) located on the silicon substrate;
a metal oxide semiconductor, formed on the SOI substrate;
a silicide layer (05), wherein a gate structure has a full silicide gate (10), a high-K dielectric layer (08) and a part for work function modification (09); and source/drain (6) are fully reacted silicides and have modified Schottky junctions.

2. The device of claim 1, wherein the gate dielectric layer (08) is selected from a thermal oxide layer or high-K dielectric layers.

3. A method of fabricating a fully-depleted SOI MOSFET device, comprising:
providing a SOI substrate, which serves as a base material of the device and has a silicon substrate (01) and an insulating layer (02) located on the silicon substrate;
forming a metal oxide semiconductor on the SOI substrate by using a semiconductor process;
selecting a silicide layer with a mid-gap work function characteristic and a dielectric layer with proper high-K, while forming source/drain/gate as fully reacted silicides;
implanting proper ions into the source/drain/gate silicides so as to perform low temperature diffusion.

4. A method of fabricating a fully-depleted SOI MOSFET device, comprising:
providing an isolating structure between devices on an insulating layer of a silicon chip by using a general isolation process;
depositing a gate dielectric layer, a poly gate electrode having a proper thickness, and forming a high-K insulating layer and a poly gate by deposition, photolithography and etch processes;
depositing a dielectric isolating layer and forming gate spacers by anisotropic etch process;
depositing a metal layer on the chip and fully depleting the silicon of the poly gate and the source/drain simultaneously by metal salicide process, and forming fully reacted silicide gate and source/drain having Schottky barrier;
implanting proper impurities into the full silicides of the gate, source and drain by ion implantation; and
performing annealing process.

5. The method of claim 4, wherein in the step of performing annealing process, for the gate structure, implanted ions are diffused into the region between the full silicide gate and the gate dielectric layer and accumulated to form a high concentration region, and for the source/drain, implanted ions are diffused into the outside of the source and drain silicides and accumulated to form high concentration regions, thereby forming a modified Schottky junction with silicde.
